(19) United States
(12) Patent Application Publication
(10) Pub. No.: US 2016/0336417 A1
(43) Pub. Date: Nov. 17, 2016

(54) SEMICONDUCTOR DEVICE AND METHOD FOR FABRICATING THE SAME

(71) Applicant: UNITED MICROELECTRONICS CORP., Hsin-Chu City (TW)

(72) Inventors: Shih-Yin Hsiao, Chiayi County (TW); Kun-Huang Yu, New Taipei City (TW); Nien-Chung Li, Hsinchu City (TW); Wen-Fang Lee, Hsinchu City (TW); Chih-Chung Wang, Hsinchu City (TW)

(21) Appl. No.: 14/749,610

(22) Filed: Jun. 24, 2015

(30) Foreign Application Priority Data
May 11, 2015 (TW) 104114958

(51) Int. Cl. H01L 29/423; H01L 27/088; H01L 29/51; H01L 29/66; H01L 21/8234; H01L 29/06

(52) U.S. Cl. CPC H01L 29/42368; H01L 21/823462; H01L 21/823481; H01L 29/0653; H01L 29/51; H01L 29/66545; H01L 27/088

(57) ABSTRACT

A method for fabricating semiconductor device is disclosed. The method includes the steps of: providing a substrate; using a first patterned mask to form a gate dielectric layer on the substrate; removing the first patterned mask; removing part of the gate dielectric layer; and forming a shallow trench isolation (STI) adjacent to two sides of the gate dielectric layer.

### BACKGROUND OF THE INVENTION

1. Field of the Invention

The invention relates to a method for fabricating semiconductor device, and more particularly, to a method of fabricating shallow trench isolation (STI) and gate dielectric layer on high voltage region of a substrate.

2. Description of the Prior Art

In current semiconductor industry, polysilicon has been widely used as a gap-filling material for fabricating gate electrode of metal-oxide-semiconductor (MOS) transistors. However, the conventional polysilicon gate also faced problems such as inferior performance due to boron penetration and unavoidable depletion effect which increases equivalent thickness of gate dielectric layer, reduces gate capacitance, and worsens driving force of the devices. In replacing polysilicon gates, work function metals have been developed to serve as a control electrode working in conjunction with high-K gate dielectric layers.

However, in current fabrication of high-k metal gate transistor, as gate dielectric layer on high-voltage region typically protrudes from the substrate surface, the metal gate formed on high-voltage region afterwards also becomes higher than the metal gate formed on low-voltage region. Consequently, a large portion of the metal gate on high-voltage region is lost by chemical mechanical polishing (CMP) process conducted thereafter. Hence, how to resolve this issue has become an important task in this field.

### SUMMARY OF THE INVENTION

According to a preferred embodiment of the present invention, a method for fabricating semiconductor device is disclosed. The method includes the steps of: providing a substrate; using a first patterned mask to form a gate dielectric layer on the substrate; removing the first patterned mask; removing part of the gate dielectric layer; and forming a shallow trench isolation (STI) adjacent to two sides of the gate dielectric layer.

According to another aspect of the present invention, a method for fabricating semiconductor device is disclosed. The method includes the steps of: providing a substrate; forming a hard mask on the substrate; forming a patterned mask adjacent to the hard mask; removing part of the substrate and the hard mask to forma first trench and a second trench adjacent to two sides of the first trench; and forming a material layer in the first trench and the second trench for forming a gate dielectric layer and a shallow trench isolation (STI) adjacent to two sides of the gate dielectric layer.

Another embodiment of the present invention discloses a semiconductor device. The semiconductor device includes: a substrate having a low voltage (LV) region and a high voltage (HV) region; a gate dielectric layer in the substrate of the HV region; and a shallow trench isolation (STI) adjacent to two sides of the gate dielectric layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 illustrate a method for fabricating semiconductor device according to a first embodiment of the present invention.

FIGS. 6-9 illustrate a method for fabricating semiconductor device according to a second embodiment of the present invention.

FIG. 10 illustrates a structural view of a semiconductor device according to an embodiment of the present invention.

### DETAILED DESCRIPTION

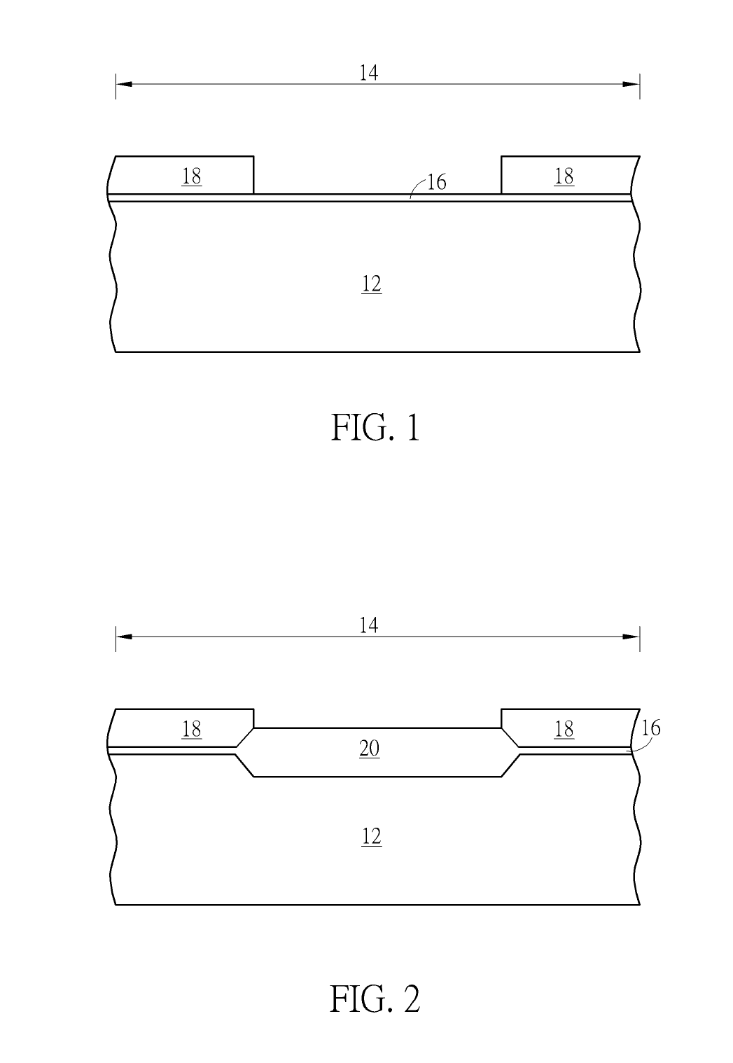

Referring to FIGS. 1-5, FIGS. 1-5 illustrate a method for fabricating semiconductor device according to a first embodiment of the present invention. As shown in FIG. 1, a substrate 12, such as silicon substrate or silicon-on-insulator (SOI) substrate is provided. A device region, such as high voltage (HV) region 14 is defined on the substrate 12, in which the HV region 14 is preferably used for fabricating a high-voltage device in the later process. In this embodiment, an oxide layer 16 is formed on the substrate 12 surface, in which the oxide layer 16 could be a native oxide layer or a thin oxide layer formed by in-situ steam generation (ISSG) on the substrate 12 surface. The oxide layer 16 is used as a buffer oxide layer, and a patterned mask 18 is formed on the oxide layer 16 thereafter. In this embodiment, the patterned mask 18 is composed of silicon nitride, but not limited thereto.

Next, as shown in FIG. 2, an oxidation process is conducted by using the patterned mask 18 as mask to form a gate dielectric layer 20 on the substrate 12. The gate dielectric layer 20 is preferably formed on the substrate 12 not covered by the patterned mask 18 while uniting with the oxide layer 16 formed earlier. In this embodiment, the gate dielectric layer 20 and the oxide layer 16 are preferably composed of same material, such as both being composed of silicon oxide, in which the thickness of the gate dielectric layer 20 is between 800 Angstroms to 2000 Angstroms, or more preferably around 1600 Angstroms.

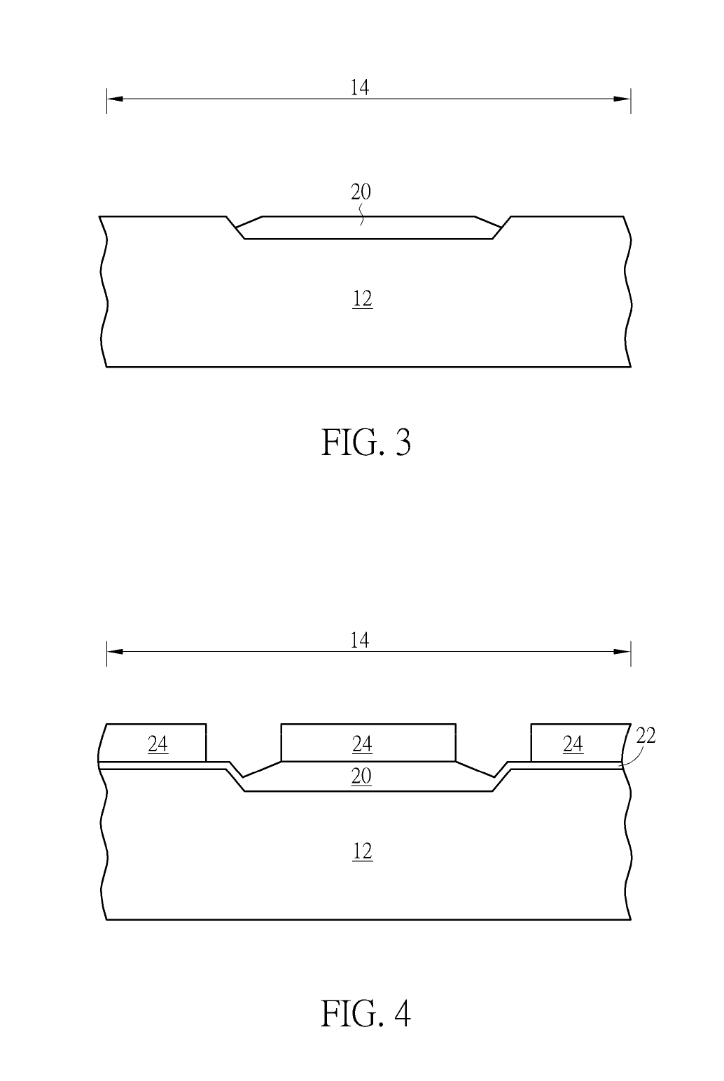

Next, as shown in FIG. 3, a dry etching or wet etching process is conducted to remove the patterned mask 18, and a wet etching is conducted to remove the oxide layer 16 and part of the gate dielectric layer 20 from the substrate 12 surface. Specifically, it would be desirable to conduct a wet etching process after stripping the patterned mask 18 to remove the oxide layer 16 surrounding the gate dielectric layer 20 for exposing the substrate 12 surface while part of the exterior gate dielectric layer 20 adjacent to the substrate 12 is removed and overall thickness of the gate dielectric layer 20 is reduced. This creates a relatively trapezoidal gate dielectric layer 20 in the substrate 12, in which the top surface of the gate dielectric layer 20 is even to or lower than the substrate 12 surface, and the two sides of the gate dielectric layer 20 adjacent to the substrate 20 are inclined downward to forma substantially trapezoidal shape altogether.

Next, as shown in FIG. 4, another oxide layer 22 serving as buffer oxide is formed on the substrate 12 surface surrounding to the gate dielectric layer 20, and another patterned mask 24 is formed on the oxide layer 22 to cover part of the oxide layer 22 and part of the gate dielectric layer 20. In this embodiment, the patterned mask 24 and gate dielectric layer 20 are preferably composed of different material, in which the patterned mask 24 could be selected from the group consisting of silicon nitride, silicon oxynitride, and silicon carbon nitride.

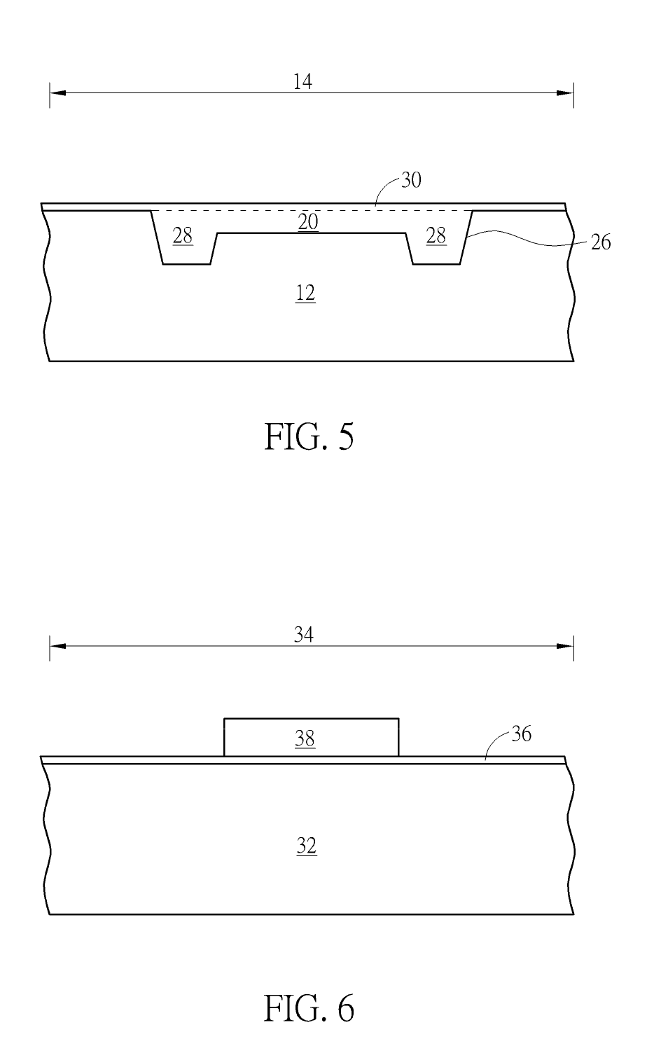

Next, as shown in FIG. 5, another etching process is conducted by using the patterned mask 24 to remove part of the oxide layer 22, part of the substrate 12, and part of the gate dielectric layer 20 to form a trench 26 around the gate dielectric layer 20 and within the substrate 12. A material layer (not shown) is then filled into the trench 26, the patterned mask 24 and oxide layer 22 are removed, and a planarizing process, such as CMP is conducted to remove part of the material layer for forming a STI 28 surrounding and directly contacting the gate dielectric layer 20, in which the top surfaces of the STI 28, gate dielectric layer 20, and substrate 12 are coplanar. In this embodiment, the material layer and gate dielectric layer 20 are composed of same material, such as both being composed of silicon oxide. Alternatively, according to another embodiment of the present invention, it would also be desirable to fill a material layer into the trench 26, use CMP to remove part of the material layer and stop on the patterned mask 24 surface, and then strip the patterned mask 24 to form the STI 28. Since the surfaces of STI 28 and gate dielectric layer 20 at this point might be slightly higher than the substrate 12 surface, a follow-up cleaning process could be conducted thereafter so that the surfaces of the STI 28, gate dielectric layer 20, and substrate 12 would be coplanar. It should be noted that if the oxide layer 22 is not removed completely, the oxide layer 22 could be removed selectively, or another oxidation process could be carried out to form another oxide layer 30 on the surfaces of the substrate 12, gate dielectric layer 20, and STI 28, in which the newly formed oxide layer 30 is preferably used as a gate dielectric layer for other low voltage devices. This completes the fabrication of a semiconductor device according to a first embodiment of the present invention.

Referring to FIGS. 6-9, FIGS. 6-9 illustrate a method for fabricating a semiconductor device according to a second embodiment of the present invention. As shown in FIG. 6, a substrate 32, such as silicon substrate or silicon-on-insulator (SOI) substrate is provided. A device region, such as high-voltage (HV) region 34 is defined on the substrate 32, in which the HV region 34 is preferably used for fabricating a high-voltage device in the later process. Similar to the aforementioned embodiment, an oxide layer 36 is formed on the substrate 32 surface, in which the oxide layer 36 could be a native oxide layer or a thin oxide layer formed by in-situ steam generation (ISSG) on the substrate 32 surface. The oxide layer 36 is used as a buffer oxide layer, and a hard mask 38 is formed on the oxide layer 36 thereafter, in which the hard mask 38 is preferably composed of silicon oxide, but not limited thereto. In this embodiment, the formation of the hard mask 38 could be accomplished by first depositing a material layer composed of silicon oxide on the oxide layer 36, and then conducting photo-etching process to remove part of the material layer for forming the hard mask 38.

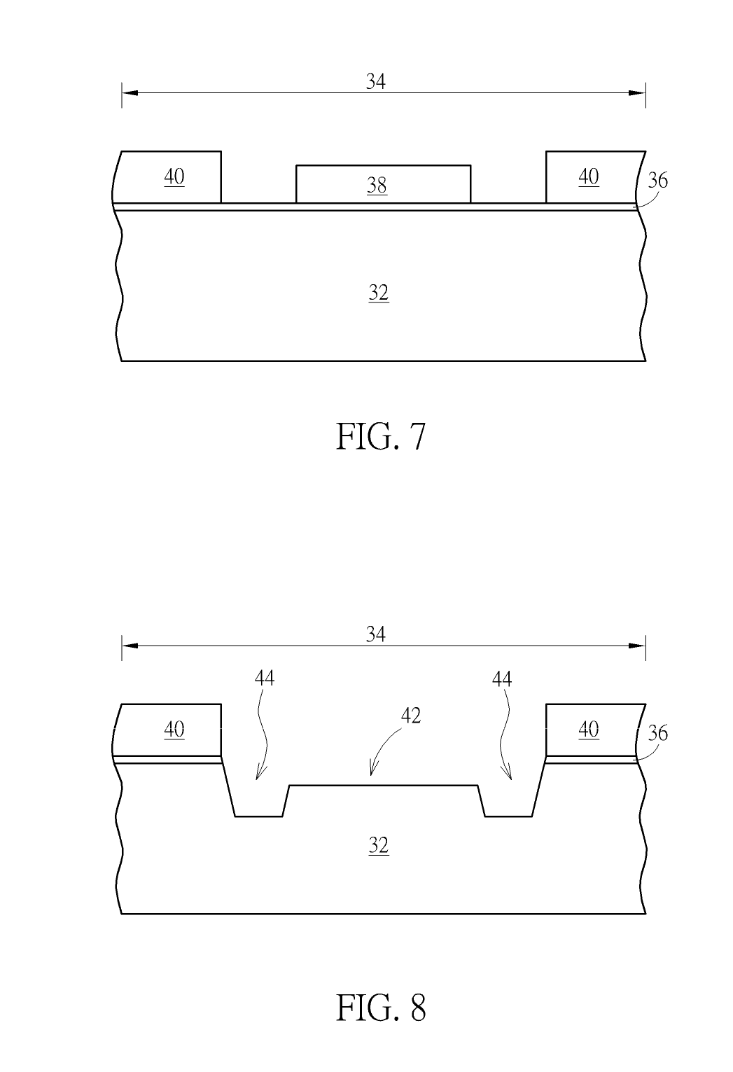

Next, as shown in FIG. 7, a patterned mask 40 is formed on the oxide layer 36 adjacent to the hard mask 38, such as surrounding the entire hard mask 38. In this embodiment, the hard mask 38 and patterned mask 40 are preferably composed of different material. For instance, when the hard mask 38 is composed of silicon oxide, the patterned mask 40 could be selected from the group consisting of silicon nitride, silicon oxynitride, and silicon carbon nitride.

Next, as shown in FIG. 8, an etching process is conducted by using the patterned mask 40 as mask to remove the hard mask 38, part of the oxide layer 36, and part of the substrate 32 for forming a first trench 42 and a second trench 44 surrounding the first trench 42 in the substrate 32. It should be noted that a difference in etching selectivity between the hard mask 38 and substrate 32 is preferably used during the removal of the hard mask 38 and part of the substrate 32 to form the first trench 42 and the second trench 44. For instance, since the hard mask 38 composed of silicon oxide has a relatively lower etching rate than the substrate composed of pure silicon, it would be desirable to use the aforementioned etching process to form first trench 42 and second trench 44 with different depths. Preferably, the bottom surface of the first trench 42 is lower than the top surface of the substrate 32 but higher than the bottom surface of the second trench 44.

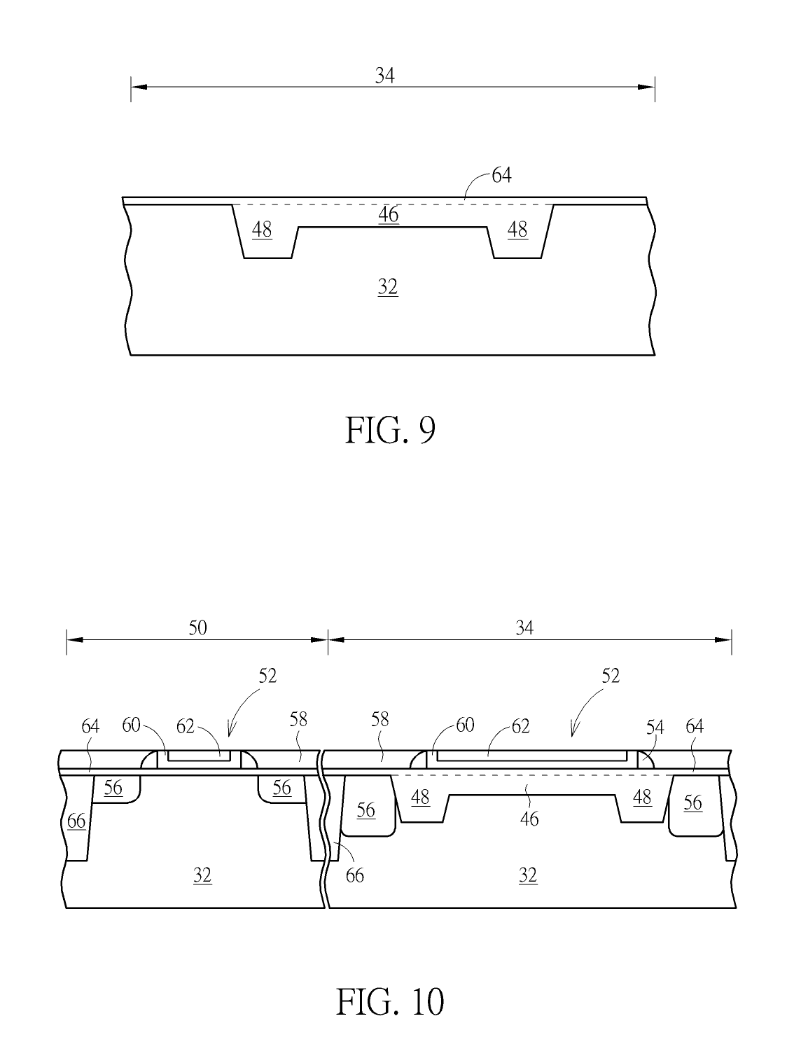

Next, as shown in FIG. 9, a material layer (not shown) composed of silicon oxide is filled into the first trench 42 and second trench 44 and onto the patterned mask 40, and a planarizing process such as CMP is conducted to remove part of the material layer, the patterned mask 40, and the oxide layer 36 so that the remaining material layer filled within the first trench 42 and second trench 44 and the surface 32 surface are coplanar. This forms a gate dielectric layer 46 in the first trench 42 and a STI 48 in the second trench 44 directly contacting the gate dielectric layer 46, in which the top surfaces of the STI 48, gate dielectric layer 46, and substrate 32 are coplanar. If the oxide layer 36 is removed along with the patterned mask 40 during the aforementioned CMP process, another oxidation process could be conducted selectively to form another oxide layer 64 atop the substrate 32, STI 48, and gate dielectric layer 46. This oxide layer 64 will be used as gate dielectric layer for other low voltage devices. This completes the fabrication of a semiconductor device according to a second embodiment of the present invention.

Referring to FIG. 10, according to an embodiment of the present invention, after STIs are formed as in FIG. 5 or FIG. 9, fabrication of transistors could be carried out in both high voltage (HV) region and low voltage (LV) region. For instance, a gate structure 52 could be formed on oxide layer 64 of each LV region 50 and HV region 34, in which the top surfaces of the gate structure 52 on LV region 50 and gate structure 52 on HV region 34 are coplanar, and the STI 66 on LV region 50 and the STI 66 outside the source/drain region 56 of HV region 34 could be formed along with the STI 48 on HV region 34.

In this embodiment, the fabrication of the metal gates 52 could be accomplished by a gate first process, a high-k first approach from gate last process, or a high-k last approach from gate last process. Since this embodiment pertains to a high-k first approach, dummy gates (not shown) composed of high-k dielectric layer and polysilicon material could be first formed on the substrate 32 of LV region 50 and HV region 34, and a spacer 54 is formed on the sidewalls of each dummy gate. A source/drain region 56 and epitaxial layer (not shown) are then formed in the substrate 32 adjacent to two sides of the spacer 54, a contact etch stop layer (CESL) (not shown) is formed on the dummy gates, and an interlayer dielectric (ILD) layer 58 composed of tetraethyl orthosilicate (TEOS) is formed on the CESL.

Next, a replacement metal gate (RMG) process could be conducted to planarize part of the ILD layer 58 and CESL and then transforming the dummy gate into a metal gate. The RMG process could be accomplished by first performing a selective dry etching or wet etching process, such as using etchants including ammonium hydroxide (NH₄OH) or tetramethylammonium hydroxide (TMAH) to remove the polysilicon layer from dummy gates for forming a recess (not shown) in the ILD layer 58. Next, a conductive layer including at least a U-shaped work function metal layer 60 and a low resistance metal layer 62 is formed in the recess, and a planarizing process is conducted so that the surfaces of the U-shaped work function layer 60 and low resistance metal layer 62 is even with the surface of the ILD layer 58. This forms a gate electrode of the gate structure 52. It should be noted that in alternative to forming STI in the substrate 32 adjacent to two sides of the gate structure on HV region as disclosed in the aforementioned two embodiments, it would also be desirable to form STI only on one side of the gate structure within the substrate on HV region, or only form a single and planar gate dielectric layer completely embedded in the substrate.

In this embodiment, the work function metal layer 60 is formed for tuning the work function of the later formed metal gates to be appropriate in an NMOS or a PMOS. For an NMOS transistor, the work function metal layer 60 having a work function ranging between 3.9 eV and 4.3 eV may include titanium aluminide (TiAl), zirconium aluminide (ZrAl), tungsten aluminide (WAl), tantalum aluminide (TaAl), hafnium aluminide (HfAl), or titanium aluminum carbide (TiAlC), but it is not limited thereto. For a PMOS transistor, the work function metal layer 60 having a work function ranging between 4.8 eV and 5.2 eV may include titanium nitride (TiN), tantalum nitride (TaN), tantalum carbide (TaC), but it is not limited thereto. An optional barrier layer (not shown) could be formed between the work function metal layer 60 and the low resistance metal layer 62, in which the material of the barrier layer may include titanium (Ti), titanium nitride (TiN), tantalum (Ta) or tantalum nitride (TaN). Furthermore, the material of the low-resistance metal layer 62 may include copper (Cu), aluminum (Al), titanium aluminum (TiAl), cobalt tungsten phosphide (CoWP) or any combination thereof. Since the process of using RMG process to transform dummy gate into metal gate is well known to those skilled in the art, the details of which are not explained herein for the sake of brevity.

Overall, the present invention discloses an approach of fabricating gate dielectric layer and STI on high-voltage device region, in which the gate dielectric layer disclosed in the aforementioned two embodiments is completely embedded within the substrate. In other words, the gate dielectric layer on HV region is extended downward into the substrate so that the top surface of the gate dielectric layer on HV region is even to or lower than the substrate surface. Since the gate dielectric layer on HV region does not protrude from the substrate surface, the metal gates formed on LV region and HV region thereafter and the top surface of ILD layer would be coplanar so that the metal gate on HV region would not be removed by CMP process as occurred in conventional art.

Those skilled in the art will readily observe that numerous modifications and alterations of the device and method may be made while retaining the teachings of the invention. Accordingly, the above disclosure should be construed as limited only by the metes and bounds of the appended claims.

1. A method for fabricating semiconductor device, comprising:
providing a substrate;
using a first patterned mask to form a gate dielectric layer on the substrate;
removing the first patterned mask;
removing part of the gate dielectric layer; and
forming a shallow trench isolation (STI) adjacent to two sides of the gate dielectric layer.

2. The method of claim 1, wherein the first patterned mask comprises silicon nitride.

3. The method of claim 1, wherein the gate dielectric layer comprises silicon oxide.

4. The method of claim 1, further comprising:
forming the first patterned mask on the substrate; and
forming the gate dielectric layer on the substrate not covered by the first patterned mask.

5. The method of claim 1, wherein the top surface of the gate dielectric layer is even to or lower than the top surface of the substrate.

6. The method of claim 1, further comprising:
performing a first etching process to remove part of the gate dielectric layer;
forming a second patterned mask on the substrate and part of the gate dielectric layer;
performing a second etching process to form a trench adjacent to two sides of the gate dielectric layer; and
filling a material layer in the trench for forming the STI.

7. The method of claim 6, wherein the second patterned mask and the gate dielectric layer comprise different material.

8. The method of claim 6, wherein the material layer and the gate dielectric layer comprise same material.

9. A method for fabricating semiconductor device, comprising:
providing a substrate;
forming a hard mask on the substrate;
forming a patterned mask adjacent to the hard mask;
removing part of the substrate and the hard mask to form a first trench and a second trench adjacent to two sides of the first trench; and
forming a material layer in the first trench and the second trench for forming a gate dielectric layer and a shallow trench isolation (STI) adjacent to two sides of the gate dielectric layer.

10. The method of claim 9, wherein the hard mask comprises silicon oxide.

11. The method of claim 9, wherein the hard mask and the patterned mask comprise different material.

12. The method of claim 9, further comprising removing the hard mask and part of the substrate directly under the hard mask to form the first trench and removing the substrate around the hard mask to form the second trench.

13. The method of claim 9, wherein the bottom surface of the first trench is lower than the top surface of the substrate and higher than the bottom surface of the second trench.

14. The method of claim 9, wherein the material layer comprises silicon oxide.

15. A semiconductor device, comprising:
a substrate having a low voltage (LV) region and a high voltage (HV) region;
a gate dielectric layer in the substrate of the HV region; and
a pair of shallow trench isolation (STI) regions adjacent to two sides of the gate dielectric layer, wherein the top surfaces of the pair of STI regions and the gate dielectric layer are coplanar.

16. The semiconductor device of claim 15, wherein the gate dielectric layer is completely inside the substrate.

17. The semiconductor device of claim 15, wherein the gate dielectric layer comprises silicon oxide.

18. The semiconductor device of claim 15, wherein the gate dielectric layer directly contacts the pair of STI regions.

19. The semiconductor device of claim 15, wherein the top surface of the gate dielectric layer is coplanar or lower than the top surface of the substrate.

20. The semiconductor device of claim 15, further comprising:
a first metal gate on the LV region; and
a second metal gate on the HV region, wherein the top surface of the first metal gate is even with the top surface of the second metal gate.
